(19) United States
(12) Patent Application Publication
(10) Pub. No.: US 2014/0264913 A1
(43) Pub. Date: Sep. 18, 2014

(54) Semiconductor Device

(71) Applicants: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(72) Inventors: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(21) Appl. No.: 13/833,464

(22) Filed: Mar. 15, 2013

(51) Int. Cl. H01L 23/48

(52) U.S. Cl. CPC H01L 23/481
USPC 257/774

(57) ABSTRACT

A semiconductor device comprises a substrate, a through-silicon via (TSV) penetrating the substrate, at least one first interconnect structure traversing the TSV from the top and dividing a region right above the TSV into several sub-regions and being configured for interconnect routing of an active device and a plurality of second interconnect structures occupying the sub-regions right above the TSV and being configured for electrically coupling the TSV to a higher-level interconnect.

### FIELD OF THE INVENTION

The present invention relates to a semiconductor device and particularly to a semiconductor device with a through-silicon via.

### BACKGROUND OF THE INVENTION

To save precious layout space or increase interconnection efficiency, multiple chips of integrated circuits (ICs) can be stacked together as a single IC package. To that end, a three-dimensional (3D) stack packaging technology is used to package the chips of integrated circuits. Through-silicon vias (TSVs) are widely used to accomplish the 3D stack packaging technology. A through-silicon via is a vertical conductive via completely passing through a silicon wafer, a silicon board, a substrate of any material or die. Nowadays, a 3D integrated circuit (3D IC) is applied to a lot of fields such as memory stacks, image sensors or the like.

Although through-silicon vias come with many advantages, they also bring some issues into integrated circuits. For example, their gigantic size (hundred times bigger than traditional transistors) compared to their neighbors such as transistors, interconnections etc. would waste a lot of layout space. The more space they waste, the bigger a chip will be. Nowadays, all the electronic devices are expected to be small so wasting space is definitely not a smart idea. Therefore, there is a need to regain some spaces taken up by the through-silicon vias.

### SUMMARY OF THE INVENTION

A purpose of this invention is to provide a semiconductor device comprising a substrate, a through-silicon via (TSV) penetrating the substrate, at least one first interconnect structure traversing the TSV from the top and dividing a region right above the TSV into several sub-regions and being configured for interconnect routing of an active device and a plurality of second interconnect structures occupying the sub-regions right above the TSV and being configured for electrically coupling the TSV to a higher-level interconnect.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 shows the schematic top view of a semiconductor device with a through-silicon via (TSV) and a portion of the interconnect structures above the TSV in accordance with an embodiment of the present invention;

FIG. 2A show the schematic cross-sectional view taken along line A-A′ in FIG. 1 in accordance with an embodiment of the present invention;

FIG. 2B show the schematic cross-sectional view taken along line A-A′ in FIG. 1 in accordance with another embodiment of the present invention;

FIG. 3A show the schematic cross-sectional view taken along line B-B′ in FIG. 1 in accordance with an embodiment of the present invention;

FIG. 3B show the schematic cross-sectional view taken along line B-B′ in FIG. 1 in accordance with another embodiment of the present invention;

FIG. 4 shows the schematic top view of a through-silicon via (TSV) and a portion of the interconnect structures above the TSV in accordance with another embodiment of the present invention;

FIG. 5 shows the schematic top view of a through-silicon via (TSV) and a portion of the interconnect structures above the TSV in accordance with still another embodiment of the present invention.

### DETAILED DESCRIPTION OF PREFERRED EMBODIMENTS

The following is the detailed description of the preferred embodiments of this invention. All the elements, sub-elements, structures, materials, arrangements recited herein can be combined in any way and in any order into new embodiments, and these new embodiments should fall in the scope of this invention defined by the appended claims. A person skilled in the art, upon reading this invention, should be able to modify and change the elements, sub-elements, structures, materials, arrangements recited herein without being apart from the principle and spirit of this invention. Therefore, these modifications and changes should fall in the scope of this invention defined only by the following claims.

There are a lot of embodiments and figures in this application. To avoid confusions, similar components are represented by same or similar numerals. To avoid complexity and confusions, only one of the repetitive components is marked. Figures are meant to deliver the principle and spirits of this invention, so the distance, size, ratio, shape, connection relationship, etc. are examples instead of realities. Other distance, size, ratio, shape, connection relationship, etc. capable of achieving the same functions or results can be adopted as equivalents.

Please refer FIG. 1, which shows the schematic top view of a semiconductor device with a through-silicon via (TSV) 1000 and a portion of the interconnect structures above the TSV 1000 in accordance with an embodiment of the present invention. The interconnect structures above the TSV 1000 comprise some conductive contacts/vias 400, some metal patterns 300 in connection with the conductive contacts/vias 400 and long metal lines 500, 501 and 502 dividing the TSV 1000 into four sub-regions, that is sub-regions 1-4. The TSV 1000 (in some references also known as through electrode, conductive post . . . etc.) passes “through” a substrate 100 (not shown in FIG. 1, please refer to FIG. 2A-3B) and physically and electrically connect the backside and front side of substrate 100. The TSV 1000 is configured to couple operation voltage VSS, VDD or operational signal to the integrated circuits (not shown) formed on the substrate 100. Compared to normal active devices such as transistors, TSV 1000 has a much bigger size in a scale of micrometers. In one embodiment, TSV 1000 has a diameter of 30 μm. In another embodiment, TSV 1000 has a diameter of 10 μm. In a further embodiment, TSV 1000 has a diameter of 6 μm.

The TSV 1000 shown in FIG. 2A-3B seems to be a TSV made from a via first process, however TSV 1000 may be made from a via first process (via is made before transistors), a via middle process (via is made after transistors and during lower interconnects) or a via last process (via is made after interconnects). No matter what kind of process is adopted to fabricate TSV 1000, the basic structure of TSV 1000 is the same: a through-silicon hole, a dielectric layer lining on the wall of the through-silicon hole, and a conductive material filled in the through-silicon hole. The material/materials used for the dielectric layer and the conductive material may depend on the manufacturing process and the physical properties needed. Silicon oxide and/or silicon nitride are the most commonly used material/materials for the dielectric layer. As to the conductive material, it may comprise a barrier/glue layer material such as Ta, TaN, Ti, TiN, W, WN, Mo, Mn, Cu and a low-resistivity material such as W, Cu, Al, poly silicon.

Refer to FIG. 1 again and FIG. 2A, the conductive contacts/vias 400 and the metal patterns 300 in connection with the conductive contacts/vias 400 in direct contact with the TSV 1000 are used to couple TSV 1000 to higher interconnect structures, hence to an external interface such as a pad or micro bump. They can be made separately by different single damascene processes (contacts/vias 400 and metal patterns 300 shown in FIG. 2)), or they can be made by the same dual damascene process in one structure (that means there is no boundary between contacts/vias 400 and metal patterns 300 and they are made of the same materials). As seen in FIG. 1, the conductive contacts/vias 400 form four arrays (2×2 arrays in FIG. 1) and all the contacts/vias 400 of the same array are connected to the same metal pattern 300. In addition, each of sub-regions 1-4 comprises only one array. In this way, the interconnect structures used to couple TSV 1000 to an external interface don't have to occupy the entire region above the TSV 1000 but divide the region above TSV 1000 into several sub-regions or save some of the area above TSV 1000 for interconnect routing of active devices such as transistors and memory cells. In the embodiment shown in FIG. 1, several long metal lines 500, 501 and 502 for interconnect routing of active devices are allowed to traverse TSV 1000 from the top and divide the region above TSV 1000 into several sub-regions. Although FIG. 1 shows three long metal lines 500, 501 and 502 for interconnect routing of active devices, four sub-regions above the TSV 1000 and 2×2 contact/via arrays in each sub-region. It is noted that more or less than 3 long metal lines can be disposed for interconnect routing of active devices, the region above the TSV 1000 can be divided into more or less than 4 sub-regions, the contact/via array may have different sizes and each sub-region may have more than one contact/via array.

An interconnect structure for “interconnect routing of active devices” means this interconnect structure is connected to a lower interconnect structure that is in direct contact with an active device, so this interconnect structure is in electrical communication with the active device through the lower interconnect structure. In the present invention, such an interconnect structure for interconnect routing of active devices should start and end not within the region right above the TSV 1000 but a part of such an interconnect structure for interconnect routing of active devices should pass through the region right above the TSV 1000. That is, all the interconnect structures used for coupling the TSV 1000 to a higher level of interconnect structures and to an external interface are not interconnect structures for interconnect routing of active devices.

Now refer to FIG. 4, which shows the schematic top view of a through-silicon via (TSV) 1000 and a portion of the interconnect structures above the TSV 1000 in accordance with another embodiment of the present invention. Two straight metal lines 500 and one L-shaped long metal line 501 and one L-shaped long metal line 502 are disposed for interconnect routing of active devices and the region above the TSV 1000 is still divided into four sub-regions (sub-regions 1-4) with smaller area of each. One 2×2 contact/via array can still fit into one sub-region, so there is no need to shrink the size of contact/via array.

Now refer to FIG. 5, which shows the schematic top view of a through-silicon via (TSV) 1000 and a portion of the interconnect structures above the TSV 1000 in accordance with still another embodiment of the present invention. One straight metal line 500 and one L-shaped long metal line 502 are disposed for interconnect routing of active devices and the region above the TSV 1000 is now divided into three sub-regions (sub-regions 1-3) with different sizes. One 2×2 contact/via array can still fit into each of the sub-regions, but it would be too empty for the sub-region 1. Two 2×2 contact/via arrays would still make the sub-region 1 look too empty, but three 2×2 contact/via arrays would make it too crowded. So two 2×1 contact/via arrays with different orientations are added into the sub-region 1.

Now refer to FIG. 2A, which shows the schematic cross-sectional view taken along line A-A′ in FIG. 1 in accordance with an embodiment of the present invention. As shown in FIG. 2A, TSV 1000 penetrates the substrate 100 and couple the front side and backside of the substrate 100. The substrate 100 can be a Si substrate, a polymer substrate, a silicon-on-insulator substrate, a SiC substrate, a composite substrate . . . etc. The backside is the side having no active devices such as transistors formed thereon. The backside of the substrate 100 is the opposite side of the front side of the substrate 100, wherein active devices such as transistors and interconnect structures are formed on the front side. Although it is not shown in FIG. 2A-3B, substrate 100 may comprise active devices, shallow trench isolation structures, memory cells thereon/therein. Disposed above the TSV 1000 is a dielectric layer 150. Dielectric layer 150 may be a single-layered or multi-layered structure comprising one or more dielectric material selected from silicon dioxide, silicon nitride, SiC, SiON, SiCN, TEOS-based silicon dioxide, low-k dielectric materials . . . etc. The conductive contacts/vias 400, metal patterns 300 in connection with the conductive contacts/vias 400, and metal line 500 and 502 for interconnect routing of active devices are all embedded in the dielectric layer 150.

Now refer to FIG. 2B, which shows the schematic cross-sectional view taken along line A-A′ in FIG. 1 in accordance with another embodiment of the present invention. Not like the embodiment shown in FIG. 2A, in this embodiment dielectric layer 150′ corresponding to the dielectric layer 150 is not directly on the TSV 1000. Between the dielectric layer 150′ and the TSV 1000 is an interconnect/device layer 130. The interconnect/device layer 130 may comprise one or more dielectric layers with interconnect structures embedded therein and/or active devices formed on substrate 100. Metal line 500′ and 502′, metal patterns 300′ and conductive contacts/vias 400′ are essentially the same as the metal line 500, metal patterns 300 and conductive contacts/vias 400 in FIG. 2A, but metal patterns 300′ and conductive contacts/vias 400′ are electrically coupled to TSV 1000 through lower interconnect structures (not shown).

Now refer to FIG. 3A, which shows the schematic cross-sectional view taken along line B-B′ in FIG. 1 in accordance with an embodiment of the present invention. FIG. 3A goes with FIG. 2A, so the dielectric layer 150 is directly on the TSV 1000. The long metal line 500 embedded in the dielectric layer 150 does not only traverse the TSV 1000 from the top but is also connected to a transistor 180 in the periphery of the TSV 1000 through a lower interconnect structure, contact 410. The long metal line 500 is usually fabricated by the same processes and from the materials used for metal patterns 300, so its detailed description will be omitted to save repetition. The transistor 180 can be an n-type MOS transistor, a p-type MOS transistor, a portion of a memory cell, or any kind of active devices made by any processes such as poly gate process, high-k first and gate first process, high-k first and gate last process, high-k last and gate last process. The lower interconnect structure is not limited to a contact in contact with the transistor 180 but may comprise a contact in contact with a doped region of an active device, a gate electrode of an active device or a pick-up region. The long metal line 500 and contact 410 may be made separately by different single damascene processes or they may be made in one structure by the same dual damascene process.

Now refer to FIG. 3B, which shows the schematic cross-sectional view taken along line B-B′ in FIG. 1 in accordance with another embodiment of the present invention. FIG. 3B goes with FIG. 2B, so the dielectric layer 150′ is not directly on the TSV 1000. Between the dielectric layer 150′ and the TSV 1000 is the interconnect/device layer 130. In this embodiment, the interconnect/device layer 130 comprise the transistor 180, a contact 420 in connection with the transistor 180 and a first metal pattern 450 embedded in a dielectric layer. Unlike the embodiment shown in FIG. 3A, the long metal 500′ is disposed in the dielectric layer 150′ and connected to the transistor 180 below it through a lower interconnect structure comprising via 410′, first metal pattern 450 and contact 420. The contact 420 and first metal pattern 450 are essentially the same as the metal line 500 and contact 410 shown in FIG. 3A except the first metal pattern 450 is much shorter than the metal line 500.

From the foregoing embodiments it is clear that by using small piece of metal patterns with contact/via arrays to couple the TSV 1000 to an external interface, the long metal line 500, 501 and 502 for interconnect routing of the transistor 180 does not have to detour in order to get around the TSV 1000 but is allowed to traverse the region right above the TSV 1000. In this way, the region right above TSVs will not be wasted and there is less restrictions for layout.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device, comprising:
a substrate;
a through-silicon via (TSV) penetrating the substrate;
at least one first interconnect structure, traversing the TSV from the top and dividing a region right above the TSV into several sub-regions, configured for interconnect routing of an active device; and
a plurality of second interconnect structures, occupying the sub-regions right above the TSV, configured for electrically coupling the TSV to a higher-level interconnect.

2. The semiconductor device of claim 1, wherein the at least one first interconnect structure and the plurality of second interconnect structures are disposed in the same dielectric layer.

3. The semiconductor device of claim 2, wherein the dielectric layer is disposed direct on the TSV and the second interconnect structures are in direct contact with the TSV.

4. The semiconductor device of claim 2, wherein the dielectric layer is disposed above the TSV and the second interconnect structures are electrically coupled to the TSV.

5. The semiconductor device of claim 1, wherein the at least one first interconnect structure comprise a long straight metal line.

6. The semiconductor device of claim 5, wherein the at least one first interconnect structure further comprise two L-shaped metal lines.

7. The semiconductor device of claim 6, wherein the region right above the TSV is divided into four sub-regions by the at least one first interconnect structure.

8. The semiconductor device of claim 7, wherein each of the sub-regions only comprise one of the plurality of second interconnect structures.

9. The semiconductor device of claim 8, wherein each of the plurality of second interconnect structures is a contact/via array and a metal layer in connection with the contact/via array.

10. The semiconductor device of claim 8, wherein each of the plurality of second interconnect structures is a contact/via array and a metal layer in one structure.

11. The semiconductor device of claim 5, wherein the at least one first interconnect structure further comprise one L-shaped metal lines.

12. The semiconductor device of claim 11, wherein the region right above the TSV is divided into three sub-regions by the at least one first interconnect structure.

13. The semiconductor device of claim 12, wherein a first sub-region of the three sub-regions is larger than a second or a third sub-region of the three sub-regions in size.

14. The semiconductor device of claim 13, wherein the first sub-region comprise more than one of the plurality of second interconnect structures while the second or third sub-region only comprise one of the plurality of second interconnect structures.

15. The semiconductor device of claim 14, wherein each of the plurality of second interconnect structures is a contact/via array and a metal layer in connection with the contact/via array.

16. The semiconductor device of claim 15, wherein the second interconnect structures in the first region are of more than one size.

17. The semiconductor device of claim 14, wherein each of the plurality of second interconnect structures is a contact/via array and a metal layer in one structure.

18. The semiconductor device of claim 15, wherein the second interconnect structures in the first region are of more than one size.

19. The semiconductor device of claim 1, wherein the active device is a transistor or a memory cell.
